(19) United States
(12) Patent Application Publication
(10) Pub. No.: US 2026/0150714 A1
(43) Pub. Date: May 28, 2026

(54) ELECTRONIC DEVICE

(71) Applicants: Advanced Semiconductor Engineering, Inc., Kaohsiung (TW); Universal Scientific Industrial (Shanghai) Co., Ltd., Shanghai (CN)

(72) Inventors: Yi-Hung HOU, Kaohsiung (TW); Jenchun CHEN, Kaohsiung (TW); Yi Chieh CHIANG, Kaohsiung (TW); Yung-Fa CHEN, Nantou County (TW); Chengchao LIAO, Nantou County (TW)

(73) Assignees: Advanced Semiconductor Engineering, Inc., Kaohsiung (TW); Universal Scientific Industrial (Shanghai) Co., Ltd., Shanghai (CN)

(21) Appl. No.: 18/963,432

(22) Filed: Nov. 27, 2024

(51) Int. Cl. H01L 23/495; H01L 23/31; H01L 23/367

(52) U.S. Cl. CPC H10W 70/461; H10W 40/22; H10W 74/111

(57) ABSTRACT

An electronic device is disclosed. The electronic device includes a first conductive plate, a plurality of first electronic components, and a plurality of second electronic components. The plurality of first electronic components are disposed on the first conductive plate and electrically connected in parallel. The plurality of second electronic components are disposed on the first conductive plate and electrically connected in parallel. The first electronic components and the second electronic components are electrically connected in series.

### BACKGROUND

### 1. Field of the Disclosure

The present disclosure relates to an electronic device, and in particular to an electronic device including a power transistor.

### 2. Description of the Related Art

As power output from power modules increases to accommodate higher charge rates, heat dissipation becomes increasingly challenging.

### SUMMARY

In some embodiments, an electronic device includes a first conductive plate, a plurality of first electronic components, and a plurality of second electronic components. The plurality of first electronic components are disposed on the first conductive plate and electrically connected in parallel. The plurality of second electronic components are disposed on the first conductive plate and electrically connected in parallel. The first electronic components and the second electronic components are electrically connected in series.

In some embodiments, an electronic device includes a first conductive plate, a first electronic component, a second electronic component, and a connecting structure. The first electronic component is disposed on the first conductive plate. The second electronic component is disposed on the first conductive plate. The connecting structure is configured to buffer stress applied to the second electronic component and electrically connect the first electronic component to the second electronic component in series.

In some embodiments, an electronic device includes a bottom conductive plate, a top conductive plate, and a protective layer. The bottom conductive plate supports a plurality of electronic components. The top conductive plate is disposed over the bottom conductive plate. The top conductive plate, the bottom conductive plate, and the electronic components collectively forms a power inverter. The protective layer encapsulates the bottom conductive plate and the top conductive plate. An upper surface of the protective layer and an upper surface of the top conductive plate are substantially coplanar.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a 3D (three dimensional) view of an exemplary electronic device according to some embodiments of the present disclosure.

FIG. 2 is an exploded view of an exemplary electronic device according to some embodiments of the present disclosure.

FIG. 3 is a 3D perspective view of a portion of an exemplary electronic device according to some embodiments of the present disclosure.

FIG. 4 is a cross-sectional view along the line A-A′ in FIG. 1.

FIG. 5 is a cross-sectional view along the line B-B′ in FIG. 1.

FIG. 6 is a top view of an exemplary conductive plate of an electronic device according to some embodiments of the present disclosure.

FIG. 7 is a top view of an exemplary conductive plate of an electronic device according to some embodiments of the present disclosure.

FIG. 8 is a top view of an exemplary conductive plate of an electronic device according to some embodiments of the present disclosure.

FIG. 9 is a perspective top view of an exemplary electronic device according to some embodiments of the present disclosure.

FIG. 10 is a circuit diagram of an exemplary electronic device according to some embodiments of the present disclosure.

FIGS. 11A, 11B, 11C, and 11D illustrate one or more stages of an exemplary method for manufacturing an electronic device according to some embodiments of the present disclosure.

FIG. 12 is a 3D view of an exemplary electronic device according to some embodiments of the present disclosure.

FIG. 13 is an exploded view of an exemplary electronic device according to some embodiments of the present disclosure.

FIG. 14 is a circuit diagram of an exemplary electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for purposes of simplicity and clarity and does not in itself dictate a relationship between the various embodiments and/or configurations discussed.

The present disclosure provides an electronic device (or a power module) capable of sustaining high voltage (e.g., higher than 800V). The electronic device includes a bottom conductive plate, a top conductive plate, and a plurality of electronic components (e.g., power dies) disposed on the bottom conductive plate. A protective layer may be formed to encapsulate the electronic components, the bottom conductive plate, and the top conductive plate. During the formation of the protective layer, stress may be applied to the electronic components via the top conductive plate, potentially deteriorating their characteristics. A connecting structure is provided between the electronic components (or the bottom conductive plate) and the top conductive plate. The connecting structure may include a plurality of stress buffers with a clip or zigzag profile. The connecting structure is configured to deform to relieve the stress from the top conductive plate to the electronic components, for example, during the process of forming a molding compound. The connecting structure buffers the stress and thus the characteristics of the electronic components are protected from the stress, improving yield.

Furthermore, the connecting structure may be configured to electrically connect a first group of the electronic components to a second group of the electronic components in series. The first group of the electronic components are connected in parallel; and the second group of the electronic components are connected in parallel. The first group and the second group are disposed on separate sections of the bottom conductive plate. These groups are self-connected in parallel and respectively arranged on the separate sections of the bottom conductive plate. As such, the risk of the electronic device failing can be reduced.

Furthermore, the power dissipation path (or the power transmission path) established in the electronic device is relatively short as compared to another electronic device which mainly horizontally dissipates power through bond wires. The power loss can be reduced. The effective resistance between the conductive plates and the electronic components may be reduced compared to the spacers which require more soldering process steps.

Furthermore, the electronic device of the present disclosure with the connecting structure requires fewer process steps as compared to another electronic device with a plurality of erecting spacers. In particular, the number of soldering process steps can be minimized. Owing to the relatively few process steps, deviation during the manufacture of the electronic device can be reduced. Furthermore, the stress buffers of the connecting structure may be flexible, allowing them to deform. The deviation (e.g., Z direction) accumulated during the manufacture and/or the thickness difference of the electronic components can be compensated by deformation of the connecting structure.

Since the deviation is reduced (e.g., less than 100 μm), the electronic device can be comparable with a standard molding process, resulting in a lower cost of the electronic device. The protective layer formed by the molding process can safeguard the electronic components from any contaminants, enhancing the reliability of the electronic device. Furthermore, the protective layer can restrict the reflow of the solders in the electronic device during high-temperature operation, thereby reducing the risk of short-circuiting.

Furthermore, the bottom conductive plate and the top conductive plate are respectively connected to a bottom heat dissipation structure and a top heat dissipation structure. The heat generated in the electronic device can be bidirectionally and vertically dissipated. The connecting structure is attached to the top conductive plate, rather than formed by stamping the top conductive plate. The bottom conductive plate and the top conductive plate can have a relatively large area for quickly dissipating the heat generated from the electronic components to the top and bottom heat dissipation structures. Since the heat dissipation is improved, the electronic device can be silver (Ag) sintering free.

In some cases, a top conductive plate may have a plurality of openings formed by the stamping process, and the molding material may overflow through the openings and then cover a top surface of the top conductive plate. In the present disclosure, the top conductive plate has a substantially rectangular shape (or opening-free) in a top view, and the overflow of the molding material can be blocked by the top conductive plate. No molding material is on the top conductive plate and thus the heat dissipation can be improved.

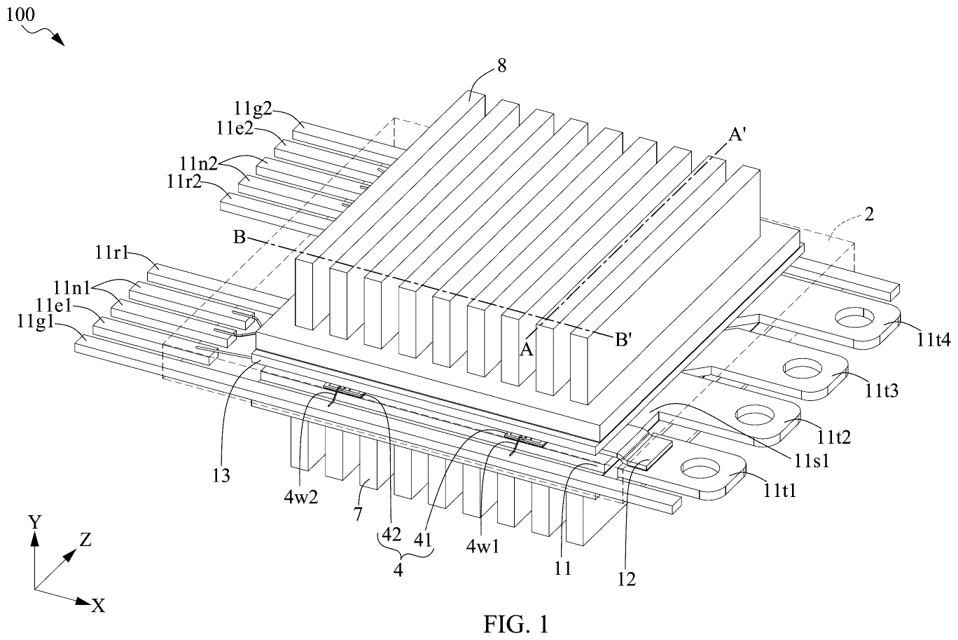

FIG. 1 is a 3D view of an exemplary electronic device (or a power module) 100 according to some embodiments of the present disclosure. The electronic device 100 may include conductive plates (or layers) 11, 12, and 13, a protective layer (or an encapsulating layer, an encapsulant) 2, a plurality of electronic components (or units) 4, a thermistor 5, a first heat dissipation structure 7, and a second heat dissipation structure 8.

As shown in FIG. 1, the conductive plate (or an intermediate conductive plate) 12 may be disposed above the conductive plate (or a bottom conductive plate) 11. The conductive plate (or a top conductive plate) 13 may be disposed above the conductive plate 12 and/or the conductive plate 11. The conductive plate 11, the conductive plate 12, and the conductive plate 13 may be stacked. The conductive plates 11, 12, and 13 may be at different elevations. On the X-Z plane, an area of the conductive plate 11 may be larger than an area of the conductive plate 13. On the X-Z plane, the area of the conductive plate 13 may be larger than an area of the conductive plate 12.

The protective layer 2 of the electronic device 100 as illustrated in FIG. 1 may be shown with dashed lines. The protective layer 2 may be transparent or opaque. The elements encapsulated by the protective layer 2 may be observed in FIG. 1 for purposes of explanation. The protective layer 2 may cover or encapsulate the conductive plate 11, the conductive plate 12, and/or the conductive plate 13. The protective layer 2 may cover at least one edge of the conductive plate 11. The protective layer 2 may cover at least one edge of the conductive plate 12. The protective layer 2 may cover at least one edge of the conductive plate 13. The protective layer 2 may protrude from an edge of the first heat dissipation structure 7 and/or the second heat dissipation structure 8 from a top view.

In some embodiments, the protective layer 2 may be formed to cover or encapsulate the conductive plates 11, 12, and/or 13 by a molding process. In the molding process, a mold (or head of a tool) may contact the conductive plates 11 and 13, and a molding material may flow into a space between the conductive plates 11 and 13.

In some embodiments, the conductive plate 11, the conductive plate 12, and the conductive plate 13 may each include conductive materials, such as copper (Cu), tin (Sn), aluminum (Al), gold (Au), silver (Ag), tungsten (W), nickel (Ni), iron (Fe), or other suitable materials.

In some embodiments, the protective layer 2 may be cuboid, cylindrical, or the like. The protective layer 2 may be electrically isolated. The protective layer 2 may include an encapsulant, such as an epoxy resin, a molding compound (e.g., an epoxy molding compound or other molding compound), a polyimide, a phenolic compound or material, a material including a silicone dispersed therein, or a combination thereof.

The conductive plate 11 may have terminals 11t1, 11t2, 11t3, and 11t4 exposed by the protective layer 2. The terminals 11t1, 11t2, 11t3, and 11t4 may protrude from the same edge of the protective layer 2. The terminals 11t2, 11t3, and 11t4 may protrude from a body portion of the conductive plate 11. The terminal 11t1 may be spaced apart from the body portion of the conductive plate 11. The terminals 11t2, 11t3, and 11t4 may have a keyhole configured to secure the conductive plate 11 to an external carrier. The extending direction of the terminals 11t1, 11t2, 11t3, and 11t4 may be orthogonal to that of the heat dissipation fins of the first heat dissipation structure 7.

The conductive plate 11 may include parts (or traces) 11g1 and 11g2 spaced apart from the body portion of the conductive plate 11. The parts 11g1 and 11g2 may extend along opposite edges of the conductive plate 11. The parts 11g1 and 11g2 may be partially exposed by the protective layer 2. The parts 11g1 and 11g2 may each include two opposite ends exposed by (or extending beyond) the protective layer 2. In other words, the parts 11g1 and 11g2 may be partially encapsulated or covered by the protective layer 2. The extending direction of the parts 11g1 and 11g2 may be orthogonal to that of the heat dissipation fins of the first heat dissipation structure 7.

The conductive plate 11 may include terminals 11e1, 11e2, 11n1, 11n2, 11r1, and 11r2 exposed by the protective layer 2. The terminals 11e1, 11e2, 11n1, 11n2, 11r1, and 11r2 may protrude from the same edge of the protective layer 2. The terminals 11r1 and 11r2 may protrude from a body portion of the conductive plate 11. The terminals 11e1, 11e2, 11n1, and 11n2 may be spaced apart from the body portion of the conductive plate 11. The extending direction of the terminals 11e1, 11e2, 11n1, 11n2, 11r1, and 11r2 may be orthogonal to that of the heat dissipation fins of the first heat dissipation structure 7.

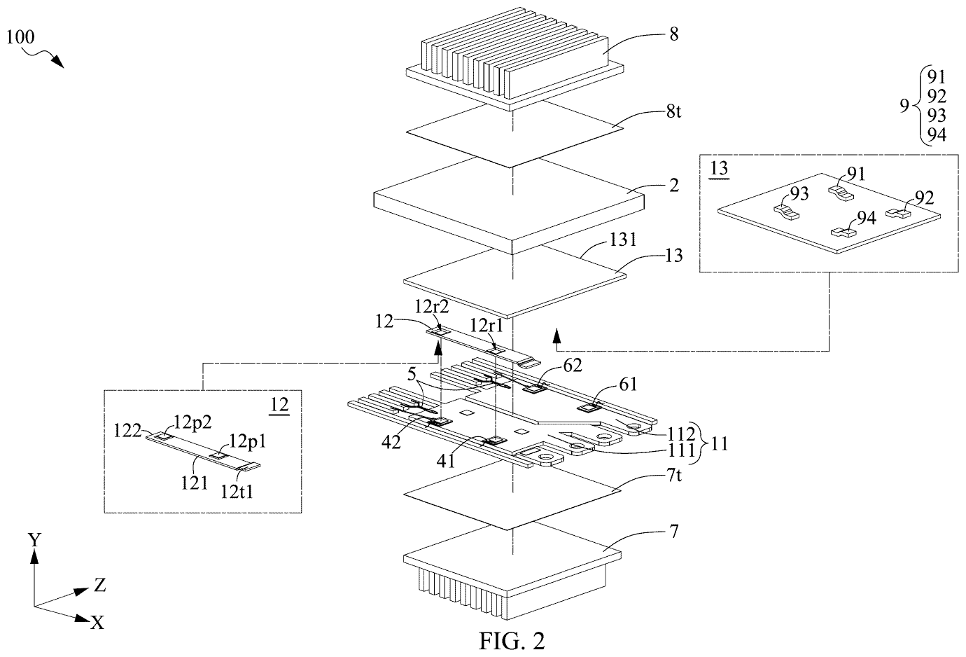

The first heat dissipation structure 7 may be disposed below the conductive plate 11. The first heat dissipation structure 7 may be in contact with the conductive plate 11. The first heat dissipation structure 7 may include a heat sink, such as heat dissipation fins, a cooling channel, or a heat dissipation plate. In some embodiments, the first heat dissipation structure 7 may be connected to an external liquid cooling system (e.g., a liquid cooling pipeline of an automobile) to dissipate the heat from the electronic device 100. The first heat dissipation structure 7 may be configured to dissipate the heat from the electronic device 100 to an external environment. The first heat dissipation structure 7 may be configured to dissipate the heat from the conductive plate 11 to an external environment. In some embodiments, the conductive plate 11 may be configured to transfer heat from the electronic components 4 (and/or electronic components 6 as shown in FIG. 2) to the first heat dissipation structure 7. The first heat dissipation structure 7 may be configured to dissipate heat from one or more of the electronic components 4 (and/or 6).

The second heat dissipation structure 8 may be disposed above the conductive plate 13. The second heat dissipation structure 8 may be in contact with the conductive plate 13. The second heat dissipation structure 8 may include a heat sink, such as heat dissipation fins, a cooling channel, or a heat dissipation plate. In some embodiments, the second heat dissipation structure 8 may be connected to an external liquid cooling system (e.g., a liquid cooling pipeline of an automobile) to dissipate the heat from the electronic device 100. The second heat dissipation structure 8 may be configured to dissipate the heat from the electronic device 100 to an external environment. The second heat dissipation structure 8 may be configured to dissipate the heat from the conductive plate 13 to an external environment. In some embodiments, the conductive plate 13 may be configured to transfer heat from the electronic components 4 (and/or electronic components 6 as shown in FIG. 2) to the second heat dissipation structure 8. The second heat dissipation structure 8 may be configured to dissipate heat from one or more of the electronic components 4 (and/or 6).

The heat generated in the electronic device 100 can be bidirectionally and vertically dissipated through the first heat dissipation structure 7 and second heat dissipation structure 8. The power dissipation path (or the power transmission path) can be shorter, reducing power loss. The conductive plate 11 is configured as the collector terminals of the electronic components 4. As such, the overall power density of the electronic device 100 can be increased while the form factor is minimized, providing high power for automobile motors.

FIG. 2 is an exploded view of an exemplary electronic device (or the electronic device 100) according to some embodiments of the present disclosure.

As shown in FIG. 2, an adhesion layer 7t may be disposed between the conductive plate 11 and the first heat dissipation structure 7. The adhesion layer 7t may connect the conductive plate 11 to the first heat dissipation structure 7. The adhesion layer 7t may include a heat dissipation gel or thermal interface material. An adhesion layer 8t may be disposed between the conductive plate 13 and the second heat dissipation structure 8. The adhesion layer 8t may connect the conductive plate 13 to the second heat dissipation structure 8. The adhesion layer 8t may include a heat dissipation gel or thermal interface material. The adhesion layers 7t and 8t may increase the thermal dissipation efficiency.

The thermistor 5 may be disposed over the conductive plate 11. The thermistor 5 may be in contact with the conductive plate 11. The thermistor 5 may include a negative temperature coefficient (NTC) thermistor which has less resistance at higher temperatures. The thermistor 5 may include a positive temperature coefficient (PTC) thermistor which has more resistance at higher temperatures. The thermistor 5 may be configured to detect the temperature of the conductive plate 11, which may represent the temperature of the electronic device 100.

The conductive plate 11 may include a portion 111 and a portion 112 disconnected from the portion 111. The portion 111 and the portion 112 may be separate. The portion 111 may be separated from the portion 112. The portion 111 and the portion 112 may be formed by partitioning a conductive material. The portion 111 and the portion 112 may be at the same elevation. The portions 111 and 112 may have different electrical potentials.

The plurality of electronic components 4 may be disposed between the conductive plate 11 and the conductive plate 12. The plurality of electronic components 4 may be disposed between the conductive plate 11 and the conductive plate 13. The plurality of electronic components 4 may be disposed above or on the conductive plate 11. The plurality of electronic components 4 may be supported by the conductive plate 11. The plurality of electronic components 4 may be disposed adjacent to an edge of the conductive plate 11. The plurality of electronic components 4 may be electrically connected to the conductive plate 11 and/or the conductive plate 12. The protective layer 2 may cover or encapsulate the electronic components 4.

The plurality of electronic components 4 may include an electronic component 41 and an electronic component 42. The number of the plurality of electronic components 4 may be 2 (two) as shown in FIG. 1. Alternatively, the number thereof may be varied, for example, 4, 8, 16 or more.

The plurality of electronic components 6 may be disposed between the conductive plate 11 and the conductive plate 13. The plurality of electronic components 6 may be disposed above or on the conductive plate 11. The plurality of electronic components 6 may be supported by the conductive plate 11. The plurality of electronic components 6 may be disposed adjacent to an edge of the conductive plate 11. The plurality of electronic components 6 may be electrically connected to the conductive plate 11 and/or the conductive plate 13. The protective layer 2 may cover or encapsulate the electronic components 6.

The plurality of electronic components 6 may include an electronic component 61 and an electronic component 62. The number of the plurality of electronic components 6 may be 2 (two) as shown in FIG. 2. Alternatively, the number thereof may be varied, for example, 6, 8, 16 or more.

The electronic components 61 and 62 may be disposed on the portion 112, while the electronic components 41 and 42 may be disposed on the portion 111. The electronic components 61 and 62 and the electronic components 41 and 42 may be at the same elevation. The electronic components 6 may not be electrically connected in parallel with the electronic components 4.

The electronic components 41, 42, 61, and 62 may include an insulated gate bipolar transistor (IGBT), SiC MOSFET, high voltage transistor, or a power transistor. In some embodiments, the electronic components 41, 42, 61, and 62 may be units which are derived or obtained from a wafer or a panel by a singulation process. Each of the electronic components 41, 42, 61, and 62 may include a semiconductor chip or die.

The conductive plate 12 may have a substantially rectangular shape. A long side 121 of the conductive plate 12 may extend in the X direction. A short side 122 of the conductive plate 12 may extend in the Z direction. The conductive plate 12 may include a plurality of recesses 12r1 and 12r2, each of which is substantially aligned with the electronic components 41 and 42, respectively. The conductive plate 12 may be viewed from different angles. For the sake of explanation, the conductive plate 12 may be turned upside down as shown in the dashed box on the left of FIG. 2. The conductive plate 12 may include a plurality of protrusions 12p1 and 12p2 on a surface opposite to the other surface on which the recesses 12r1 and 12r2 are disposed. The recesses 12r1 and 12r2 may be disposed directly above the protrusions 12p1 and 12p2. The recesses 12r1 and 12r2 and the protrusions 12p1 and 12p2 may be formed by stamping the conductive plate 12.

The conductive plate 12 may further include a terminal 12t1 substantially aligned with a terminal of the conductive plate 11. The terminal 12t1 may have a ladder profile. The terminal 12t1 may have a clip profile or zigzag profile.

The conductive plate 13 may have a substantially rectangular shape. Each of the four sides 131 of the conductive plate 13 has a linear profile (or straight line). The contact area between the conductive plate 13 and the adhesion layer 8t may be increased to improve the thermal dissipation efficiency. The conductive plate 13 may be viewed from different angles. For the purpose of explanation, the conductive plate 13 may be turned upside down as shown in the dashed box on the right of FIG. 2.

The electronic device 100 may include a connecting structure 9. The connecting structure 9 may be disposed on the conductive plate 13. The connecting structure 9 may be mounted on or attached to the conductive plate 13 through an adhesion layer (not shown). In some embodiments, the connecting structure 9 may be wedged to the conductive plate 13. As shown in FIG. 2, the connecting structure 9 may be completely covered by the conductive plate 13 (e.g., in the Y direction). The connecting structure 9 may be disposed between the conductive plate 11 and the conductive plate 13.

The connecting structure 9 may include a plurality of connecting portions (or conductive elements) 91, 92, 93, and 94. The connecting portions 91, 92, 93, and 94 may have a ladder profile, a clip profile, or a zigzag profile. The connecting structure 9 (e.g., the connecting portions 93 and 94) may be flexible to relieve the stress applied to the electronic components 6. The connecting portions 91, 92, 93, and 94 may be referred to as stress buffers and configured to deform to relieve the stress. The number of the plurality of connecting portions may be 4 (four) as shown in FIG. 2. Alternatively, the number thereof may be varied, for example, 2, 8, 16, or more. The number of the connecting portions may be more than the number of the electronic components.

In some embodiments, the connecting portions 91, 92, 93, and 94 may each include conductive materials, such as copper (Cu), tin (Sn), aluminum (Al), gold (Au), silver (Ag), tungsten (W), nickel (Ni), iron (Fe), or other suitable materials.

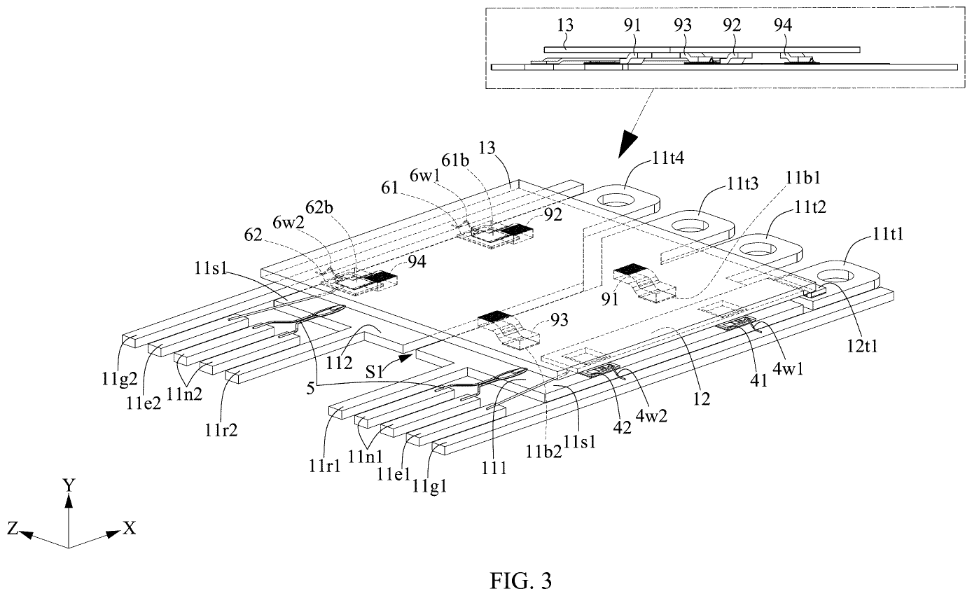

FIG. 3 is a 3D perspective view of a portion of an exemplary electronic device (e.g., the electronic device 100) according to some embodiments of the present disclosure. FIG. 3 shows the structure, connections, and/or relationships among the conductive plate 11, the conductive plate 12, the conductive plate 13, the electronic components 41, 42, 61, and 62, and the connecting portions 91, 92, 93, and 94 of the connecting structure 9.

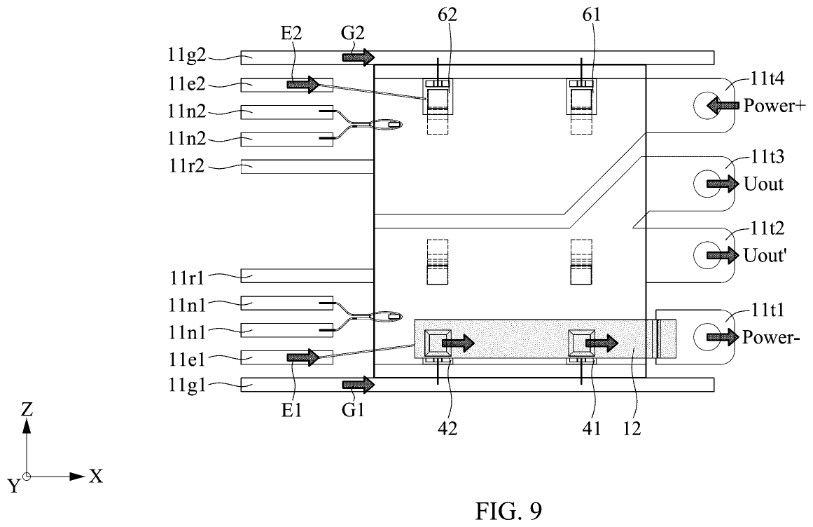

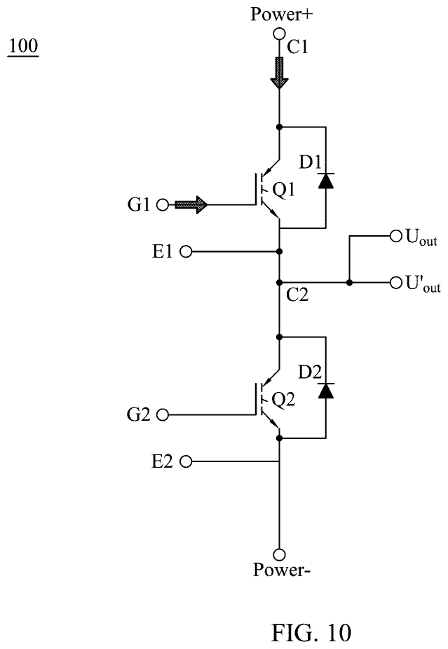

The portion 111 and the portion 112 may be spaced apart from each other with a spacing S1. The spacing S1 may be winding on the Z-X plane. The portion 111 of the conductive plate 11 may be connected to the terminals 11t2 and 11t3. The portion 112 may be connected to the terminal 11t4. The portion 111 may be spaced apart from the terminal 11t1. The portion 111 may support the electronic component 41 (and/or 42) and be configured to provide an output power signal (e.g., Uₒᵤₜ and U′ₒᵤₜ as shown in FIGS. 9 and 10) to an external device (e.g., a motor, automobile electric motor). The portion 112 may support the electronic component 61 (and/or 62) and be configured to receive an input power signal (e.g., Power+ as shown in FIGS. 9 and 10).

The connecting portions 91 and 93 may be disposed over the portion 111 of the conductive plate 11. The connecting portions 92 and 94 may be disposed over the portion 112 of the conductive plate 11. The connecting portions 92 and 94 may be spaced apart from the conductive plate 11. The connecting portion 92 may be disposed over the electronic component 61, and the connecting portion 94 may be disposed over the electronic component 62. The conductive plate 11 may support the conductive plate 13 through the connecting portion 92 and/or 94. The electronic component 61 and/or 62 may support the conductive plate 13 through the connecting portion 92 and/or 94. In some embodiments, the connecting portions 92 and 94 may be configured to buffer stress applied to the electronic components 61 and 62. The connecting structure 9 may be configured to deform to relieve the stress from the conductive plate 13 to the electronic components 61 and 62, for example, during the process of forming the protective layer 2. The connecting structure 9 can buffer the stress and thus the characteristics of the electronic components 61 and 62 are protected from the stress, thereby improving yield.

Furthermore, the connecting structure 9 is attached to the conductive plate 13, rather than formed by stamping the conductive plate 13. The conductive plate 11 and the conductive plate 13 can have a relatively large area for quickly dissipating the heat generated from the electronic components 4 and 6 to the first and second heat dissipation structures 7 and 8. Since the heat dissipation is improved, the electronic device 100 can be silver (Ag) sintering free.

The conductive plates 11 and 13 may be spaced apart from each other by the connecting structure 9. The connecting structure 9 may retain the space between the conductive plates 11 and 13 for accommodating the conductive plate 12. The conductive plate 12 may be adjacent to an edge of the conductive plate 11. The conductive plate 12 may be free from (vertically) overlapping the connecting structure 9 in a direction perpendicular to an upper surface 11s1 of the conductive plate 11 (or the Y direction). The conductive plate 12 may be configured to electrically connect the electronic components 41 and 42 (e.g., their emitter terminals) to the terminal 11t1 of the conductive plate 11. The terminal 11t1 may be a power terminal of the electronic device 100. The conductive plate 12 may (vertically) overlap the electronic components 41 and 42, while being free from (vertically) overlapping the electronic components 61 and 62. Owing to the intermediate conductive plate 2, the dimension along the Y direction can be reduced.

In some embodiments, the conductive plate 13, the conductive plate 11, and the electronic components 41, 42, 61, and 62 may collectively form a power inverter (as shown in FIG. 10).

The electronic device 100 may include a plurality of wirings 4w1 and 4w2, each connecting the electronic component 41 and the electronic component 42 to the part 11g1 of the conductive plate 11. The part 11g1 of the conductive plate 11 may include a common electrode electrically connected to a gate terminal of each of the electronic components 41 and 42. The wirings 4w1 and 4w2 may include a bond wire or be formed by a wire-bonding apparatus. Each of the electronic components 41 and 42 may have a collector terminal connected to the conductive plate 11. Each of the electronic components 41 and 42 may have an emitter terminal connected to the conductive plate 12. The collector terminals of the electronic components 41 and 42 are electrically connected and the emitter terminals of the electronic components 41 and 42 are electrically connected. That is, the electronic components 41 and 42 may be electrically connected in parallel.

The electronic device 100 may include a plurality of wirings 6w1 and 6w2, each connecting the electronic component 61 and the electronic component 62 to the part 11g2 of the conductive plate 11. The part 11g2 of the conductive plate 11 may include a common electrode electrically connected to a gate terminal of each of the electronic components 61 and 62. The wirings 6w1 and 6w2 may include a bond wire or be formed by a wire-bonding apparatus. Each of the electronic components 61 and 62 may have a collector terminal connected to the portion 112 of the conductive plate 11. Each of the electronic components 61 and 62 may have an emitter terminal electrically connected to the conductive plate 13 through the connecting portion (or a conductive element) 92 and the connecting portion (or a conductive element) 94. The connecting portions 92 and 94 may be respectively connected to the electronic components 61 and 62 (e.g., the emitter terminal thereof) through solder materials 61b and 62b. The collector terminals of the electronic components 61 and 62 are electrically connected and the emitter terminals of the electronic components 61 and 62 are electrically connected. That is, the electronic components 61 and 62 may be electrically connected in parallel.

The conductive plate 13 may be electrically connected to the conductive plate 11 through the connecting portion (or a conductive element) 91 and/or the connecting portion (or a conductive element) 93 of the connecting structure 9. The connecting portions 91 and 93 may be respectively connected to the conductive plate 11 through solder materials 11b1 and 11b2. The collector terminals of the electronic components 41 and 42 may be electrically connected to the emitter terminals of the electronic components 61 and 62 through the conductive plate 13, the connecting portions 91, 92, 93, and 94 of the connecting structure 9, and/or the conductive plate 11. At least one of the electronic components 41 and 42 and at least one of the electronic components 61 and 62 may be electrically connected in series through the conductive plate 13.

Hence, the connecting structure 9 may be configured to buffer stress applied to at least one of the electronic components 61 and 62 and electrically connect at least one of the electronic components 41 and 42 to at least one of the electronic components 61 and 62 in series. The connecting structure 9 configured as a stress buffer may reduce, lessen, or eliminate the stress applied to the electronic components 61 and 62. The connecting portions 91, 92, 93, and 94 of the connecting structure 9 may deform to relieve the stress applied to the electronic components 61 and 62, for example, during the process of forming the protective layer 2. The connecting portions 91, 92, 93, and 94 can buffer said stress and thus the characteristics of the electronic components 61 and 62 are protected from the stress, thereby improving yield.

A first group (e.g., the electronic components 41 and 42) and a second group (e.g., the electronic components 61 and 62) are disposed on the separated portions 111 and 112 of the conductive plate 11. These groups are self-connected in parallel and arranged on separate sections of the conductive plate 11. As such, the risk of the electronic device 100 failing can be reduced.

The power dissipation path (or the power transmission path) established in the electronic device 100 is relatively short as compared to another electronic device which mainly horizontally dissipates power through bond wires. The power loss can be reduced. The effective resistance between the conductive plates 11 and 13 and the electronic components 41, 42, 61, and 62 may be reduced compared to the spacers which require more soldering process steps.

The thermistor 5 may be connected to the terminals 11n1 and 11n2 of the conductive plate 11. The terminal 11r1 may protrude from the portion 111 of the conductive plate 11. The terminal 11r2 may protrude from the portion 112 of the conductive plate 11. The terminals 11r1 and 11r2 may be referred to as reserved pins for the electronic device 100. The terminal 11e1 may be connected to the emitter terminal of the electronic component 42 through a wire. The terminal 11e2 may be connected to the emitter terminal of the electronic component 62 through a wire.

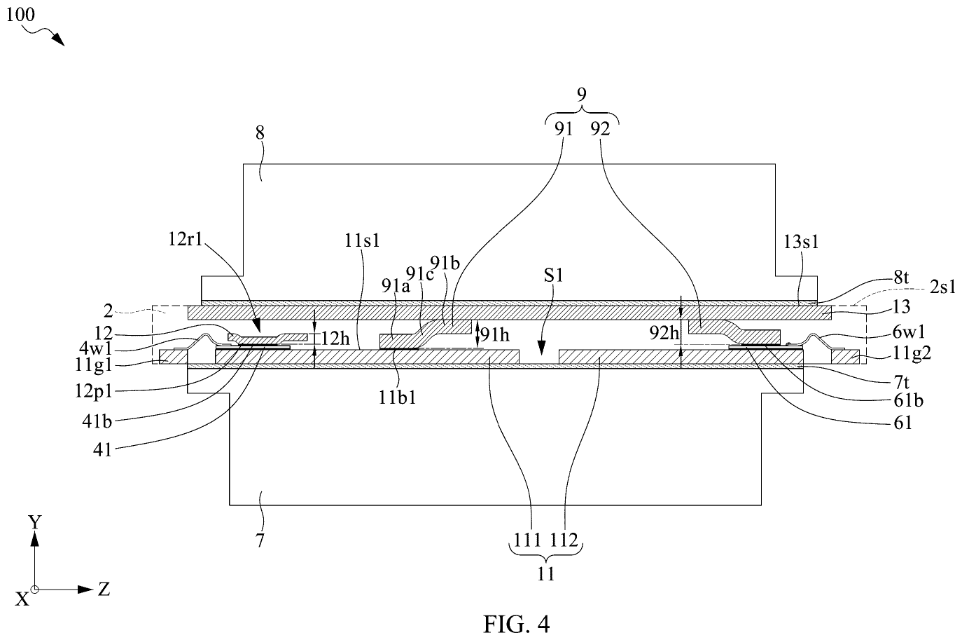

FIG. 4 is a cross-sectional view along the line A-A′ in FIG. 1.

The protective layer 2 may be formed to cover the conductive plates 11, 12, and/or 13 by a molding process. In the molding process, a mold (or head of a tool) may contact the conductive plates 11 and 13, and a molding material may flow into a space between the conductive plates 11 and 13. The conductive plate 13 has a substantially rectangular shape (or opening-free), and the overflow of the molding material can be blocked by the conductive plate 13. No molding material is on the conductive plate 13 and thus the heat dissipation can be improved. An upper surface 2s1 of the protective layer 2 and an upper surface 13s1 of the conductive plate 13 may be substantially coplanar. The upper surface 2s1 may be continuous with the upper surface 13s1.

The protective layer 2 formed by the molding process can protect the electronic components 41, 42, 61, and 62 from any contaminants. The reliability of the electronic device 100 can be improved. Furthermore, the protective layer 2 can restrict the reflow of the solder materials 41b, 11b1, and 61b during high-temperature operation, thereby eliminating the risk of short-circuiting.

The electronic component 41 and the electronic component 61 may be respectively disposed on the portion 111 and the portion 112 of the conductive plate 11. The portions 111 and 112 may be spaced apart by the protective layer 2, which may fill in the spacing S1.

The protrusion 12p1 of the conductive plate 12 may be connected to the electronic component 41 through a solder material 41b. The connecting portion 91 may be connected to the conductive plate 11, while connecting portion 92 may be connected to the electronic component 61. In the Y direction (or a direction perpendicular to the upper surface 11s1), a height (or thickness) 91h of the connecting portion 91 may be different from a height (or thickness) 92h of the connecting portion 92. Since there is an additional element (i.e., the electronic component 61) under the connecting portion 92, the height 92h may be less than the height 91h. In some embodiments, top surfaces of the connecting portions 91 and 92 may be at the same elevation, while bottom surfaces of the connecting portions 91 and 92 may not be at the same elevation with respect to the upper surface 11s1 of the conductive plate 11. In the Y direction (or a direction perpendicular to the upper surface 11s1), a height 12h (or thickness) of the conductive plate 12 may be less than a height 91h of the connecting portion 91 of the connecting structure 9.

In some embodiments, the connecting portion 91 may have a first section 91a in contact with the conductive plate 11, a second section 91b disposed above the first section and in contact with the conductive plate 13, and a third section 91c connecting the first section 91a to the second section 91b. The third section 91c may be non-perpendicular to the first section 91a and the second section 91b. The sidewalls of the third section 91c may be parallel with each other. Both of the sidewalls of the third section 91c may be substantially curved. The first section 91a, the second section 91b, and the third section 91c may collectively form a clip, ladder, or zigzag shape. The connecting portions 92, 93, and 94 may have a similar structure to that of the connecting portion 91 and thus the detailed descriptions of the connecting portions 92, 93, and 94 can refer to those for the connecting portion 91.

The electronic device 100 with the connecting structure 9 requires fewer process steps as compared to another electronic device with a plurality of erecting spacers. In particular, the number of soldering process steps can be minimized. Owing to the relatively few process steps, deviation during the manufacture of the electronic device 100 can be reduced. Furthermore, the stress buffers of the connecting structure may be flexible, allowing them to deform. The deviation (e.g., Y direction) accumulated during the manufacture and/or the thickness difference of the electronic components can be compensated by the deformation of the connecting structure 9.

Since the deviation is reduced (e.g., less than 100 μm), the electronic device 100 can be comparable with a standard molding process, resulting in a lower cost of the electronic device 100.

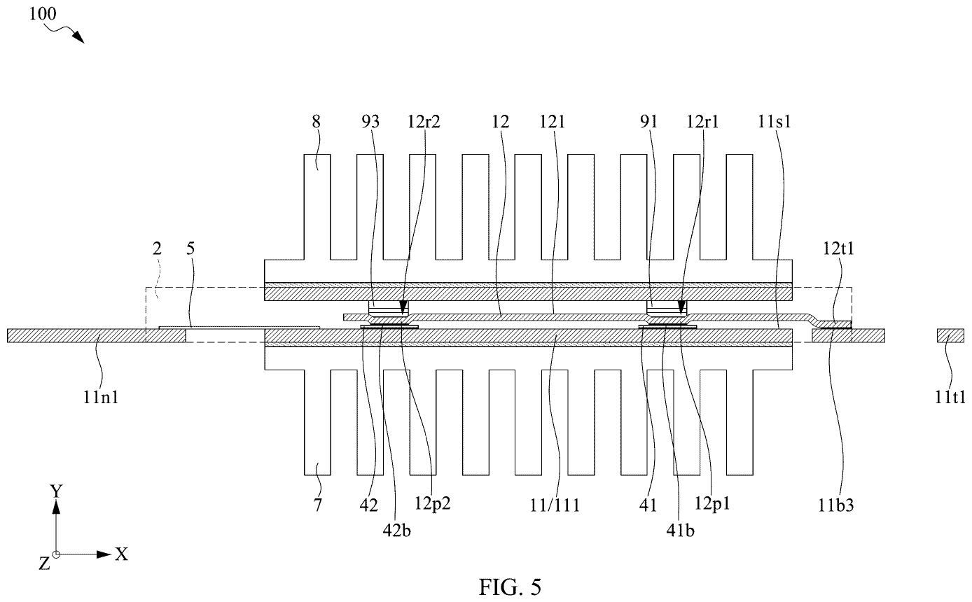

FIG. 5 is a cross-sectional view along the line B-B′ in FIG. 1.

The recesses 12r1 and 12r2 may be disposed directly above the protrusions 12p1 and 12p2. In the Z direction (perpendicular to the long side 121 of the conductive plate 12 and parallel to the upper surface 11s1 of the conductive plate 11), the recesses 12r1 and 12r2 may respectively overlap the connecting portions 91 and 93.

The terminal 12t1 of the conductive plate 12 may be connected to the terminal 11t1 through a solder material 11b3. An outer side of the terminal 12t1 of the conductive plate 12 may be covered by the protective layer 2. The thermistor 5 may be encapsulated or covered by the protective layer 2.

The first heat dissipation structure 7 may have a fin structure to increase the surface area of the first heat dissipation structure 7. The second heat dissipation structure 8 may have a fin structure to increase the surface area of the second heat dissipation structure 8. The adhesion layer 7t may protrude from the protective layer 2. The adhesion layer 8t may protrude from the protective layer 2.

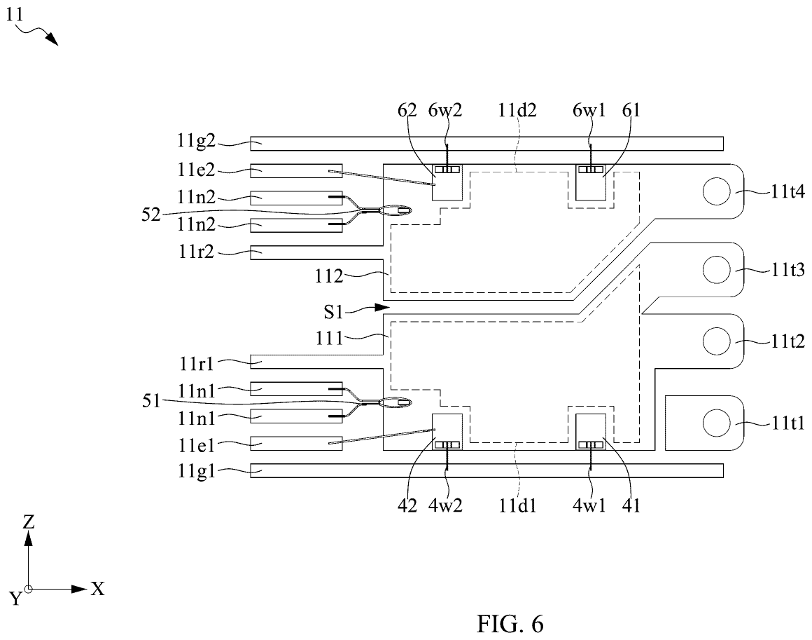

FIG. 6 is a top view of an exemplary conductive plate (e.g., the conductive plate 11) of an electronic device (e.g., the electronic device 100) according to some embodiments of the present disclosure.

The electronic device may include a thermistor 51 disposed on the portion 111 and a thermistor 52 disposed on the portion 112 of the conductive plate 11. The thermistor 51 may be in contact with the portion 111. The thermistor 52 may be in contact with the portion 112. The thermistors 51 and 52 may each include a negative temperature coefficient (NTC) thermistor which has less resistance at higher temperatures. The thermistors 51 and 52 may each include a positive temperature coefficient (PTC) thermistor which has more resistance at higher temperatures. The thermistors 51 and 52 may be configured to detect the temperature of the conductive plate 11, which may represent the temperature of the electronic device 100.

The portion 111 of the conductive plate 11 may include a region 11d1 for arranging or mounting a diode. The diode may be electrically connected in parallel with the electronic components 41 and 42. The diode may be configured to provide a transmission path for the reverse current. The portion 112 of the conductive plate 11 may include a region 11d2 for arranging or disposing a diode. The diode may be electrically connected in parallel with the electronic components 61 and 62. The diode may be configured to provide a transmission path for the reverse current.

In some embodiments, the electronic device 100 may not include a diode since the conductive plate 11 is large enough for transmitting the reverse current.

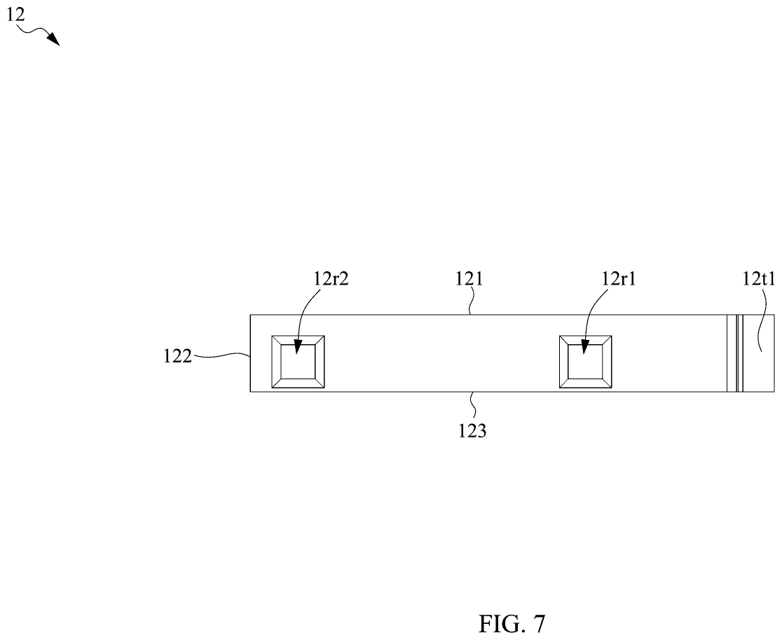

FIG. 7 is a top view of an exemplary conductive plate (e.g., the conductive plate 12) of an electronic device (e.g., the electronic device 100) according to some embodiments of the present disclosure.

The recesses 12r1 and 12r2 may be disposed closer to a side 123 than to a side (or the long side) 121. The recess 12r1 may be closer to the terminal 12t1 than to the recess 12r2.

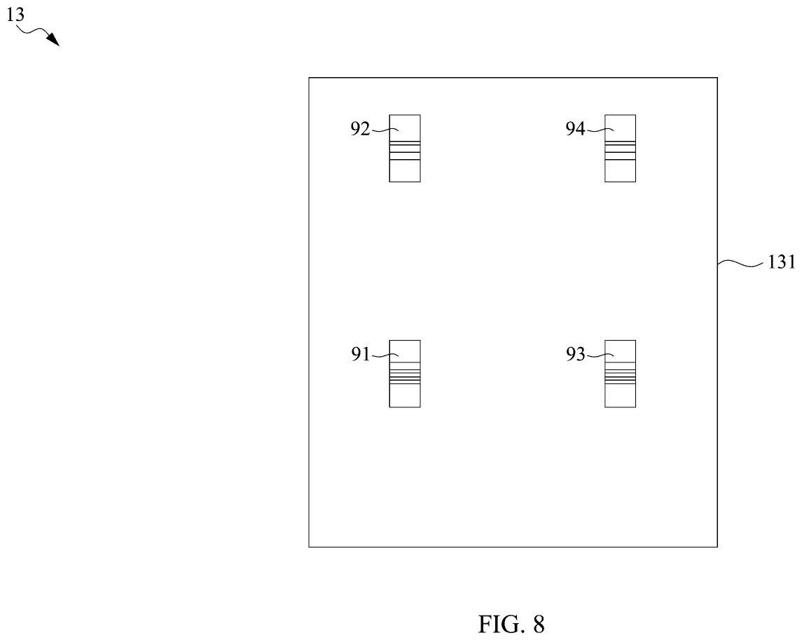

FIG. 8 is a top view of an exemplary conductive plate (e.g., the conductive plate 13) of an electronic device (e.g., the electronic device 100) according to some embodiments of the present disclosure.

The connecting portions 91 and 93 may be symmetrical to the connecting portions 92 and 94. In a top view, each of the four sides 131 of the conductive plate 13 has a linear profile (or straight line).

FIG. 9 is a perspective top view of an exemplary electronic device (e.g., the electronic device 100) according to some embodiments of the present disclosure.

As shown in FIG. 9, the conductive plate 11, the conductive plate 12, and the conductive plate 13 are stacked. In the Y direction (or a direction perpendicular to the upper surface 11s1 of the conductive plate 11), the conductive plate 12 may overlap the electronic components 41 and 42 and be free from overlapping the electronic components 61 and 62.

The arrows Uₒᵤₜ, U′ₒᵤₜ, G1, E1, G2, and E2 indicate the pins as described in FIG. 10. The arrows Power+and Power-indicate the power supplies as described in FIG. 10. FIG. 10 is a circuit diagram of an exemplary electronic device (e.g., the electronic device 100) according to some embodiments of the present disclosure. The electronic device 100 may include a power inverter.

A transistor Q1 may represent the electronic components 61 and 62. A pin C1 may be connected to a collector terminal of the transistor Q1 and configured to receive a power signal from a power supply Power+. A pin G1 may be connected to a gate terminal of the transistor Q1 and configured to receive a control signal. A pin E1 may be connected to an emitter terminal of the transistor Q1.

A transistor Q2 may represent the electronic components 41 and 42. A pin C2 may be connected to the pin E1. The emitter of the transistor Q1 may be connected to a collector terminal of the transistor Q2. A pin G2 may be connected to a gate terminal of the transistor Q2 and configured to receive a control signal. A pin E1 may be connected to an emitter terminal of the transistor Q2 and configured to receive a power signal from a power supply Power−.

When the transistors Q1 and Q2 turn on, the electronic device 200 may be configured to output a power signal to the pin Uₒᵤₜ and the pin U′ₒᵤₜ. The pin Uₒᵤₜ and the pin U′ₒᵤₜ may be electrically connected to an external device, such as a motor, automobile electric motor. The power signal may include a three phase power signal.

In some embodiments, the transistor Q1 may be electrically connected to a diode D1. The diode D1 may be configured to protect the transistor Q1 from damage caused by the reverse current. The transistor Q2 may be electrically connected to a diode D2. The diode D2 may be configured to protect the transistor Q2 from damage caused by the reverse current. In some embodiments, the electronic device 100 may not include the diodes D1 and D2 since the conductive plates 11 and 13 are large enough to sustain the reverse current.

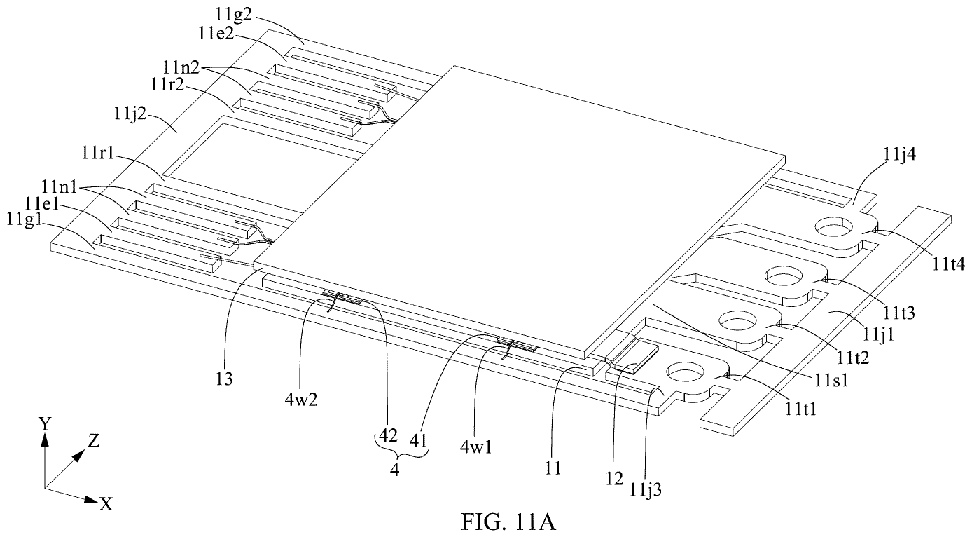

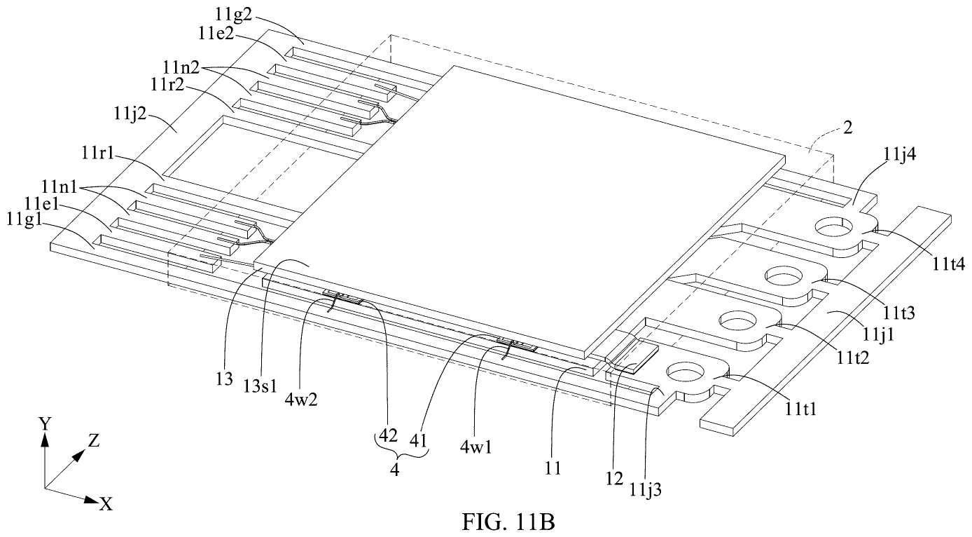

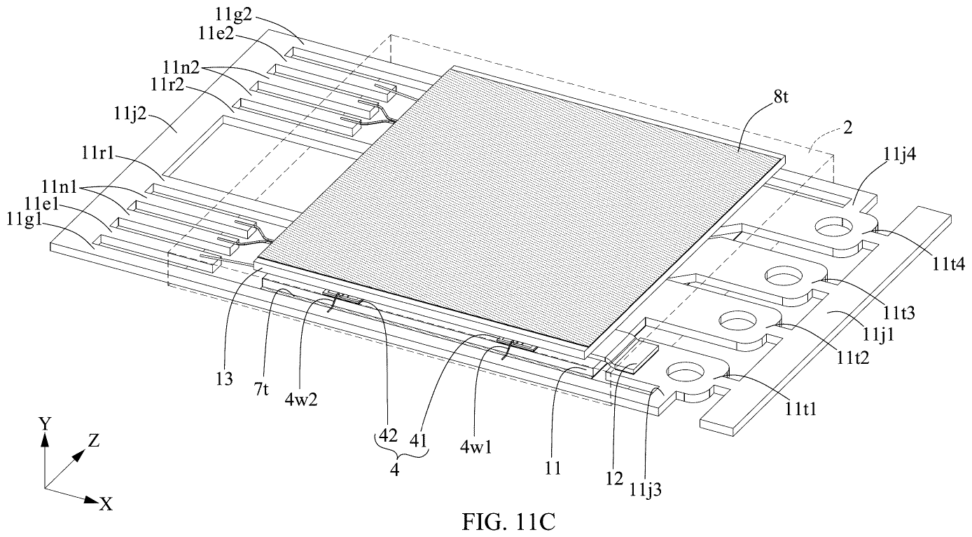

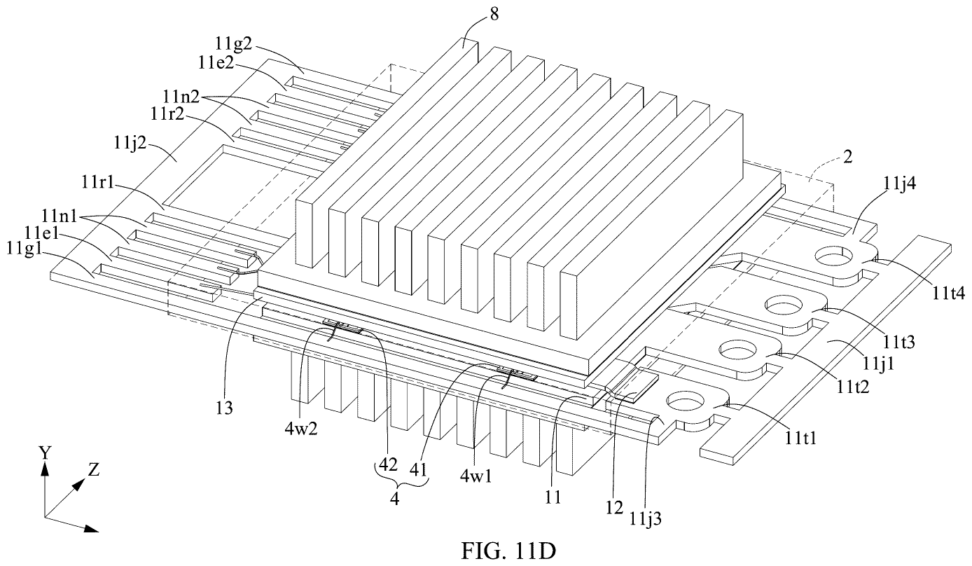

FIGS. 11A, 11B, 11C, and 11D illustrate one or more stages of an exemplary method for manufacturing an electronic device according to some embodiments of the present disclosure.

As shown in FIG. 11A, a conductive plate 11 may be provided. The conductive plate 11 may include terminals 11t1, 11t2, 11t3, and 11t4 at the same side. The terminals 11t1, 11t2, 11t3, and 11t4 may be connected to a joint portion 11j1.

The conductive plate 11 may include terminals 11e1, 11e2, 11n1, 11n2, 11r1, and 11r2 at the same side. The terminals 11e1, 11e2, 11n1, 11n2, 11r1, and 11r2 may be connected to a joint portion 11j2.

The conductive plate 11 may include parts (or traces) 11g1 and 11g2 at opposite sides. The part 11g1 may be connected to the joint portion 11j2. The part 11g1 may be connected to the joint portions 11j1 and 11j2. The part 11g1 may be connected to a joint portion 11j3 which is also connected to the terminal 11t1. The part 11g2 may be connected to a joint portion 11j4 which is also connected to the terminal 11t4.

A plurality of electronic components 41 and 42 may be disposed over the conductive plate 11. The electronic components 41 and 42 may be connected to the part 11g1 through wirings 4w1 and 4w2, respectively.

A conductive plate 12 may be mounted to the conductive plate 11 and the electronic components 41 and 42. A conductive plate 13 may be mounted to the conductive plate 11 and a plurality of electronic components 61 and 62 (not shown) through a connecting structure 9 (referring to FIG. 2). The conductive plates 11, 12, and 13 may be stacked.

As shown in FIG. 11B, a protective layer 2 may be formed to encapsulate or cover the stacking structure of the conductive plates 11, 12, and 13 by a molding process. The terminals 11e1, 11e2, 11n1, 11n2, 11r1, and 11r2 may be exposed by the protective layer 2. The terminals 11t1, 11t2, 11t3, and 11t4 may be exposed by the protective layer 2. The parts 11g1 and 11g2 may be partially exposed by the protective layer 2, with each having two ends extending beyond the protective layer 2. During the formation of the protective layer 2, a mold (or a head of a tool) would apply force to the conductive plate 13 and the connecting structure 9 (not shown) may experience the stress from the conductive plate 13 and subsequently deform to buffer the stress from the conductive plate 13 to the electronic components 41, 42, 61, and 62. An upper surface 13s1 of the conductive plate 13 may be exposed by the protective layer 2. A lower surface (not shown) of the conductive plate may be exposed by the protective layer 2.

As shown in FIG. 11C, an adhesion layer 7t may be formed on the conductive plate 11 and an adhesion layer 8t may be formed on the conductive plate 13. The adhesion layer 8t may include a heat dissipation gel or thermal interface material. The adhesion layers 7t and 8t may increase the thermal dissipation efficiency.

As shown in FIG. 11D, a first heat dissipation structure 7 may be formed on the adhesion layer 7t and a second heat dissipation structure 8 may be formed on the adhesion layer 8t. The first heat dissipation structures 7 and 8 may include a heat sink, such as heat dissipation fins, a cooling channel, or a heat dissipation plate.

Afterwards, the joint portions 11j1, 11j2, 11j3, and 11j4 may be removed by a cutting or stamping process to form the electronic device 100 as shown in FIG. 1.

The electronic device 100 with the connecting structure 9 requires fewer process steps as compared to another electronic device with a plurality of erecting spacers. In particular, the number of soldering process steps can be minimized. Owing to the relatively few process steps, deviation during the manufacture of the electronic device 100 can be reduced. Furthermore, the stress buffers of the connecting structure may be flexible, allowing them to deform. The deviation (e.g., Y direction) accumulated during the manufacture and/or the thickness difference of the electronic components can be compensated by the deformation of the connecting structure 9.

Since the deviation is reduced (e.g., less than 100 μm), the electronic device 100 can be comparable with a standard molding process, resulting in a lower cost of the electronic device 100.

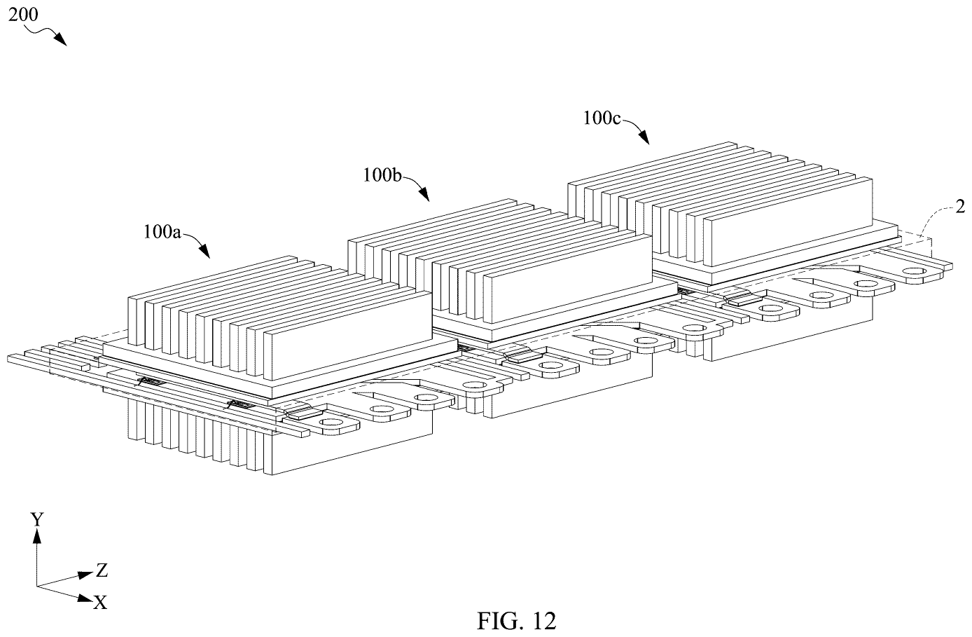

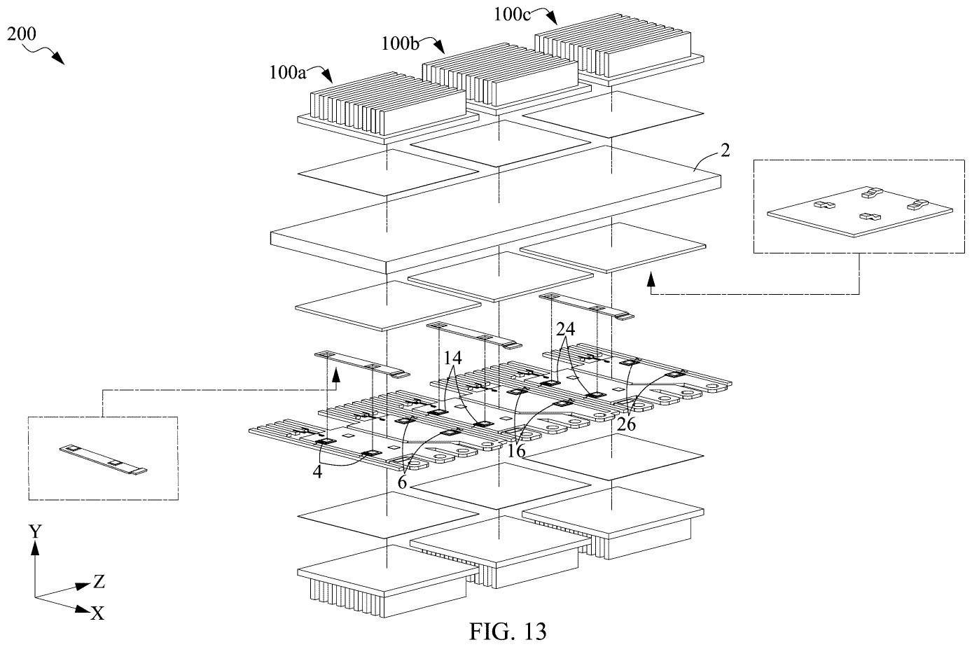

FIG. 12 is a 3D view of an exemplary electronic device (or a power module) 200 according to some embodiments of the present disclosure. FIG. 13 is an exploded view of the electronic device according to some embodiments of the present disclosure. The electronic device 200 may include a plurality of electronic devices 100a, 100b, and 100c. Each of the electronic devices 100a, 100b, and 100c of FIGS. 12 and 13 may be similar to the electronic device 100 of FIGS. 1, 2, 3, 4, 5, 6, 7, 8, 9, and 10. Therefore, some detailed descriptions may correspond to preceding paragraphs and are not repeated hereinafter for conciseness, with differences therebetween as follows.

The conductive plates of the electronic devices 100a, 100b, and 100c may be encapsulated or covered by the same protective layer (e.g., the protective layer 2). The number of the plurality of electronic devices 100 a, 100 b, and 100 c may be 3 (three) as shown in FIG. 12. Alternatively, the number thereof may be varied, for example, 2, 4, 5 or more. The electronic devices 100a, 100b, and 100c may be arranged in a 3×1 array. Alternatively, the electronic devices 200 may include a 2×2 array, 2×3 array, or more.

The electronic device 100a may include the electronic components 4 and the electronic components 6 disposed on a bottom conductive plate. The electronic device 100b may include a plurality of electronic components 14 and a plurality of electronic components 16 disposed on a bottom conductive plate. The electronic device 100c may include a plurality of electronic components 24 and a plurality of electronic components 26 disposed on a bottom conductive plate. The electronic components 14 and electronic components 24 may be similar to the electronic components 4. The electronic components 16 and electronic components 26 may be similar to the electronic components 6.

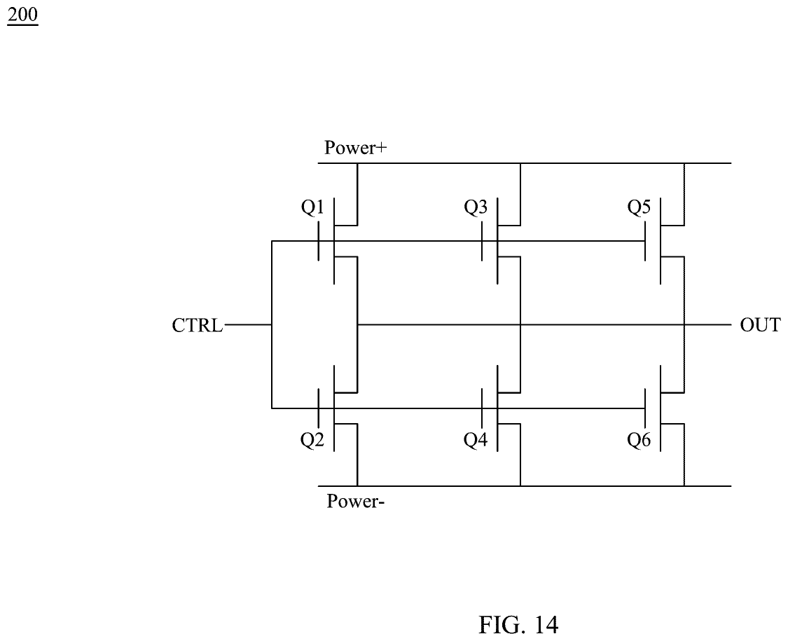

FIG. 14 is a circuit diagram of an exemplary electronic device (e.g., the electronic devices 200) according to some embodiments of the present disclosure.

The electronic device 200 may include transistors Q1, Q2, Q3, Q4, Q5, and Q6. The transistor Q1 may represent the electronic components 6. The transistor Q2 may represent the electronic components 4. The transistor Q3 may represent the electronic components 16. The transistor Q4 may represent the electronic components 14. The transistor Q5 may represent the electronic components 26. The transistor Q6 may represent the electronic components 24.

The transistors Q1, Q3, and Q5 may each have a collector terminal connected to a power supply Power+. The transistors Q1, Q3, and Q5 may each have a gate terminal configured to receive a control signal CTRL. The transistors Q1, Q3, and Q5 may each have an emitter terminal connected to an output terminal OUT.

The transistors Q2, Q4, and Q6 may each have a collector terminal connected to the emitter terminals of the transistors Q1, Q3, and Q5. The transistors Q2, Q4, and Q6 may each have a gate terminal configured to receive the control signal CTRL. The transistors Q2, Q4, and Q6 may each have an emitter terminal connected to a power supply Power−.

When the transistors Q1, Q2, Q3, Q4, Q5, and Q6 turn on, the electronic device 200 may be configured to output a power signal to the output terminal OUT. The output terminal OUT may be electrically connected to a motor. The power signal may include a three phase power signal.

The transistors Q2, Q4, and Q6 may be connected in parallel to provide relatively high current. The transistors Q2, Q4, and Q6 may form a low side power switch. The transistors Q1, Q3, and Q5 may be connected in parallel to provide relatively high current. The transistors Q1, Q3, and Q5 may form a low side power switch. The more transistors there are, the higher the voltage that the electronic device 200 can process or sustain. In some embodiments, the voltage may be higher than 800V, 1200V, or more.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first conductive plate;
a plurality of first electronic components disposed on the first conductive plate and electrically connected in parallel; and
a plurality of second electronic components disposed on the first conductive plate and electrically connected in parallel,
wherein the first electronic components and the second electronic components are electrically connected in series.

2. The electronic device of claim 1, further comprising a second conductive plate configured to electrically connect the first electronic components to the second electronic components in series.

3. The electronic device of claim 2, further comprising a first conductive element connecting the first conductive plate to the second conductive plate.

4. The electronic device of claim 3, wherein the second conductive plate is electrically connected to a collector terminal of one of the first electronic components through the first conductive element.

5. The electronic device of claim 4, further comprising a second conductive element connecting the second conductive plate to one of the second electronic components.

6. The electronic device of claim 5, wherein the second conductive element is connected an emitter terminal of one of the second electronic component.

7. The electronic device of claim 1, wherein the first electronic components and the second electronic components are respectively disposed on a first portion and a second portion of the first conductive plate, wherein the first portion is spaced apart from the second portion with a first spacing.

8. The electronic device of claim 6, wherein the second conductive element is spaced apart from the first conductive plate.

9. The electronic device of claim 2, further comprising a third conductive plate disposed between the first conductive plate and the second conductive plate, wherein the third conductive plate connects the first electronic components to a power terminal.

10. The electronic device of claim 9, further comprising an encapsulant encapsulating the first electronic components, the second electronic components, the first conductive plate, the second conductive plate, and the third conductive plate.

11. An electronic device, comprising:
a first conductive plate;
a first electronic component disposed on the first conductive plate;
a second electronic component disposed on the first conductive plate; and
a connecting structure configured to buffer stress applied to the second electronic component and electrically connect the first electronic component to the second electronic component in series.

12. The electronic device of claim 11, wherein the first electronic component and the second electronic component are disposed adjacent to an edge of the first conductive plate, the first electronic component is disposed on a first portion of the first conductive plate, and the second electronic component is disposed on a second portion of the first conductive plate, and wherein the first portion and the second portion are separate.

13. The electronic device of claim 11, further comprising a second conductive plate disposed above the first conductive plate, wherein a height of the second conductive plate is less than a height of the connecting structure.

14. The electronic device of claim 11, wherein the first conductive plate comprises a first portion and a second portion separated from the first portion, and wherein the first portion supports the first electronic component and is configured to provide an output power signal to an external device, and the second portion supports the second electronic component and is configured to receive input power signal.

15. The electronic device of claim 14, further comprising a third conductive plate disposed above the first conductive plate and connected to the first portion.

16. The electronic device of claim 14, wherein the connecting structure comprises a first section in contact with the first conductive plate, a second section disposed above the first section, and a third section connecting the first section to the second section, and wherein the third section is non-perpendicular to the first section and the second section.

17. An electronic device, comprising:
a bottom conductive plate supporting a plurality of electronic components;
a top conductive plate disposed over the bottom conductive plate, wherein the top conductive plate, the bottom conductive plate, and the electronic components collectively forms a power inverter; and
a protective layer encapsulating the bottom conductive plate and the top conductive plate,
wherein an upper surface of the protective layer and an upper surface of the top conductive plate are substantially coplanar.

18. The electronic device of claim 17, further comprising a first heat dissipation structure disposed below the bottom conductive plate and a second heat dissipation structure disposed above the top conductive plate.

19. The electronic device of claim 18, wherein the protective layer protrudes from an edge of the second heat dissipation structure from a top view.

20. The electronic device of claim 17, wherein the bottom conductive plate comprises a first portion and a second portion spaced apart from each other by the protective layer.
